(19) United States
(12) Patent Application Publication
(10) Pub. No.: US 2025/0379929 A1
(43) Pub. Date: Dec. 11, 2025

(54) WINDOW, ELECTRONIC DEVICE INCLUDING THE SAME, AND METHOD OF MANUFACTURING WINDOW

(71) Applicant: Samsung Display Co., LTD., Yongin-si (KR)

(72) Inventors: MIJIN KIM, Yongin-si (KR); Seungkuk KUK, Yongin-si (KR); TAEHO AN, Yongin-si (KR)

(21) Appl. No.: 19/190,205

(22) Filed: Apr. 25, 2025

(30) Foreign Application Priority Data
Jun. 5, 2024 (KR) 10-2024-0073390

(51) Int. Cl. H04M 1/02

(52) U.S. Cl. CPC H04M 1/0266

(57) ABSTRACT

A window for a display device includes a flat portion including a crystalline glass, and a curved portion including glass having a crystallinity degree lower than a crystallinity degree of the flat portion and coupled to the flat portion, where the curved portion is curved with respect to the flat portion, and a front surface of the curved portion includes a curved surface, and a front surface of the flat portion includes only a flat surface.

This application claims priority to Korean Patent Application No. 10-2024-0073390, filed on Jun. 5, 2024, and all the benefits accruing therefrom under 35 U.S.C. § 119, the content of which in its entirety is herein incorporated by reference.

### BACKGROUND

### (1) Field

Embodiments of the present disclosure described herein relate to a window, an electronic device including the window, and a method of manufacturing a window, and more particularly, relate to a curved window, an electronic device including the window, and a method of manufacturing a window.

### (2) Description of the Related Art

Windows of electronic devices of mobile devices such as mobile phones and smart phones and wearable devices such as smart watches are desired to have high light transparency to visually recognize images displayed therethrough. Further, for ease of movement, the windows may be desired to have a small thickness and high strength.

Glass for the window may be manufactured in a three-dimensional (3D) shape having a curved surface to improve operability, visibility, and an aesthetic sense of electronic devices.

### SUMMARY

Embodiments of the present disclosure provide a three-dimensional (3D) window for a display device, which has at least one curved surface and has improved light transmittance and improved processability.

According to an embodiment, a window includes a flat portion including a crystalline glass, and a curved portion including glass having a crystallinity degree lower than a crystallinity degree of the flat portion and coupled to the flat portion, where the curved portion is curved with respect to the flat portion, and a front surface of the curved portion includes a curved surface, and a front surface of the flat portion includes only a flat surface.

In an embodiment, a joining area may be defined between the flat portion and the curved portion, and the joining area may be formed of only glass.

In an embodiment, the joining area may have a frame shape surrounding an edge of the flat portion in a plan view.

In an embodiment, the curved portion may be provided in plural and a plurality of curved portions may be spaced part from each other with the flat portion interposed therebetween, and the joining area may be provided in plural and a plurality of joining areas may be provided on one side and an opposing side of the flat portion.

In an embodiment, the flat portion may include glass having a crystallinity degree of about 60% or greater.

In an embodiment, the curved portion may include amorphous glass.

In an embodiment, a rear surface of the curved portion may include a flat surface.

In an embodiment, a rear surface of the curved portion may include a curved surface.

In an embodiment, a rear surface of the flat portion may have a same area as the front surface of the flat portion.

In an embodiment, a rear surface of the flat portion may have a smaller area than the front surface of the flat portion.

According to an embodiment, an electronic device includes a display panel including a flat surface, a window disposed on the display panel, and a housing disposed under the display panel and coupled with the window, where the window includes a flat portion corresponding to the flat surface and including a first member, and a curved portion including a second member having a crystallinity degree lower than a crystallinity degree of the first member and coupled to the flat portion, and the curved portion includes a surface inclined with respect to a front surface of the flat portion.

In an embodiment, the flat portion may have a light transmittance higher than a light transmittance of the curved portion.

In an embodiment, the curved portion may have ductility higher than ductility of the flat portion.

In an embodiment, the flat portion may have impact resistance higher than impact resistance of the curved portion.

In an embodiment, the display panel may display an image only on the flat portion.

In an embodiment, the display panel may display an image on the flat portion and the curved portion.

According to an embodiment, a method of manufacturing a window includes providing a flat portion formed of a first member and including a first front surface which is flat, a first rear surface which is opposite to the first front surface and flat, and an outer surface connected between the first front surface and the first rear surface, providing a curved portion formed of a second member different from the first member and including a second front surface including a surface inclined with respect to the first front surface, a second rear surface opposite to the second front surface, and a side surface connected between the second front surface and the second rear surface, assembling the flat portion and the curved portion to form a joining line in which the outer surface of the flat portion faces at least a portion of the side surface of the curved portion, and joining the flat portion and the curved portion to form a joining area along the joining line through a plasma fusion bonding process.

In an embodiment, the first member may include crystalline glass, and the second member may include glass having a crystallinity degree lower than a crystallinity degree of the first member.

In an embodiment, the crystallinity degree of the first member may be about 60% or greater.

In an embodiment, the second member may include amorphous glass.

In an embodiment, the flat portion and the curved portion may be physically separated from each other along the joining line in the assembling of the flat portion, and the curved portion and may be physically coupled to each other along the joining area in the joining of the flat portion and the curved portion.

In an embodiment, the curved portion may be formed through a chamfering process.

In an embodiment, the curved portion may be formed through a bending process.

### BRIEF DESCRIPTION OF THE DRAWINGS

The above and other features of embodiments of the present disclosure will become apparent by describing in detail embodiments thereof with reference to the accompanying drawings.

FIG. 1A is a perspective view of a coupled state of an electronic device according to an embodiment of the present disclosure.

FIG. 1B is an exploded perspective view of the electronic device illustrated in FIG. 1A.

FIG. 2 is a plan view illustrating some components of a display panel according to an embodiment of the present disclosure.

FIG. 3A is a perspective view of the electronic device according to an embodiment of the present disclosure.

FIG. 3B is an exploded perspective view of the electronic device illustrated in FIG. 1A.

FIGS. 4A and 4B are cross-sectional views of the electronic device illustrated in FIG. 3A.

FIG. 5A is a perspective view of the electronic device according to an embodiment of the present disclosure.

FIG. 5B is an exploded perspective view of the electronic device illustrated in FIG. 5A.

FIGS. 6A and 6B are cross-sectional views of the electronic device illustrated in FIG. 5A.

FIGS. 7A and 7B are cross-sectional views of a window according to an embodiment of the present disclosure.

FIG. 8 is a schematic flowchart illustrating a method of manufacturing a window according to an embodiment of the present disclosure.

FIGS. 9A to 9E are views illustrating the method of manufacturing the window according to an embodiment of the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

In the specification, the expression that a first component (or an area, a layer, a part, a portion, etc.) is “connected with” or “coupled to” a second component means that the first component is directly connected with/coupled to the second component or means that a third component is interposed therebetween.

The same reference numerals refer to the same components. Further, in the drawings, the thickness, the ratio, and the dimension of components are exaggerated for effective description of technical contents.

The term “and/or” includes all combinations of one or more components that may be defined by associated configurations.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical terms and scientific terms) used in the specification have the same meaning as commonly understood by those skilled in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described with reference to the accompanying drawings.

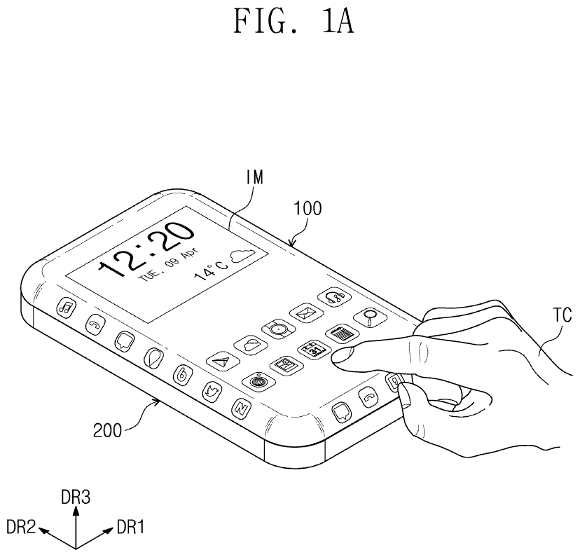

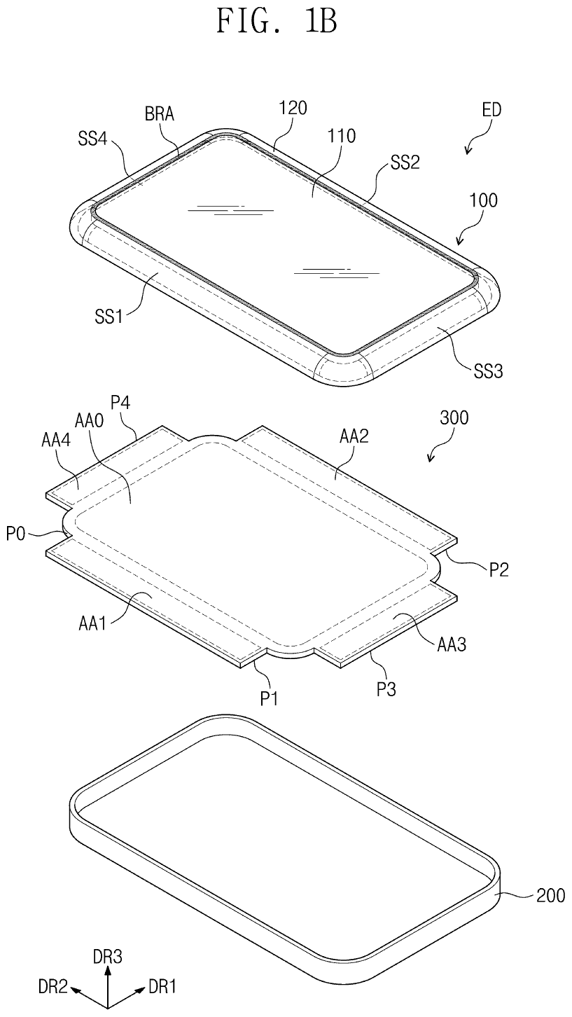

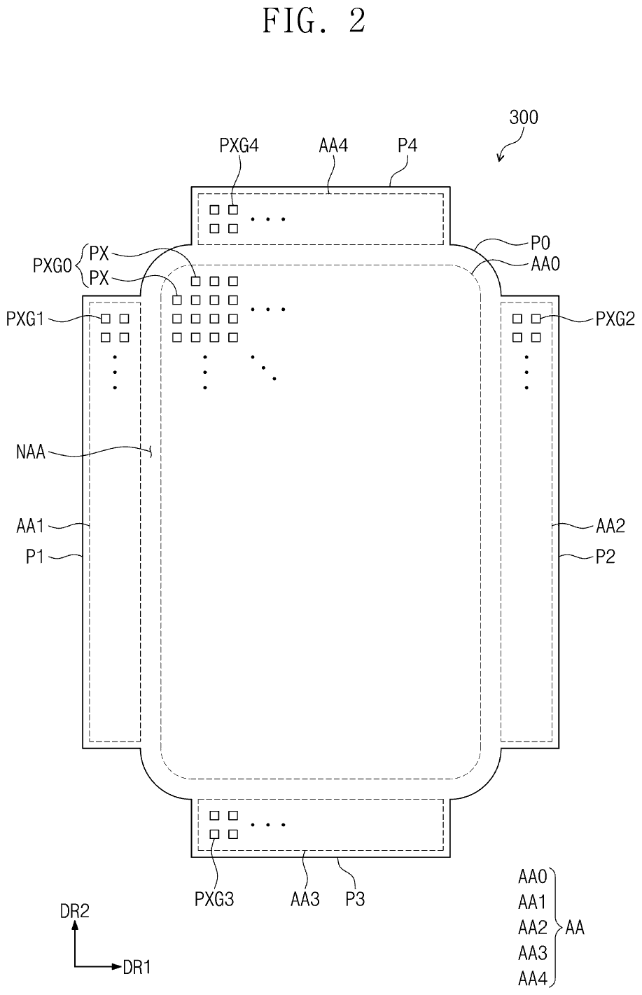

FIG. 1A is a perspective view of a coupled state of an electronic device according to an embodiment of the present disclosure. FIG. 1B is an exploded perspective view of the electronic device illustrated in FIG. 1A. FIG. 2 is a plan view illustrating some components of a display panel according to an embodiment of the present disclosure. Hereinafter, an embodiment of the present disclosure will be described with reference to FIGS. 1A to 2.

An embodiment of an electronic device ED may display an image IM. The image IM includes a still image and a dynamic image. Further, the electronic device ED may sense an input TC of a user, which is applied from the outside. The input TC (hereinafter, referred to as an external input) of the user may include various of external inputs such as a portion of a human body of the user, a light, heat, pressure, or the like. Further, the electronic device ED may sense an input close to or adjacent to the electronic device ED as well as an input in contact with the electronic device ED. In an embodiment, as shown in FIG. 1A, the electronic device ED may be a smartphone, and the external input TC may be a touch or contact by a hand of the user. In an embodiment, the external input TC may include a pressure and a touch.

In an embodiment, as shown in FIG. 1B, the electronic device ED may include a window 100, a housing 200, and a display panel 300. The window 100 protects a front surface of the display panel 300. The window 100 may be optically transparent. Accordingly, the image IM displayed on a display panel 300 may pass through the window 100 and may be visually recognized by the user. The window 100 may include or be made of glass. In an embodiment, for example, the window 100 may be a glass window.

In an embodiment, the window 100 may include at least a portion thereof that is curved on a cross section defined by a first direction DR1 and a second direction DR2. The window 100 includes a front surface (e.g., a flat portion 110), a first side surface SS1, a second side surface SS2, a third side surface SS3, and a fourth side surface SS4.

In an embodiment, the front surface may be a surface perpendicular to a third direction DR3. Each of the first side surface SS1, the second side surface SS2, the third side surface SS3, and the fourth side surface SS4 is curved from the front surface. Each of the first side surface SS1 and the second side surface SS2 may be a surface that is curved from the front surface and extending in the second direction DR2. The first side surface SS1 and the second side surface SS2 may be opposite to each other in the first direction DR1.

Each of the third side surface SS3 and the fourth side surface SS4 may be a surface that is curved from the front surface and extending in the first direction DR1. The third side surface SS3 and the fourth side surface SS4 may be opposite to each other in the second direction DR2.

In an embodiment, the window 100 may include a plurality of surfaces through which the image IM is displayed. In an embodiment, for example, the window 100 may include the front surface and the plurality of side surfaces SS1, SS2, SS3, and SS4, and the image IM may be disposed on the side surfaces SS1, SS2, SS3, and SS4 as well as the front surface. However, this is illustratively illustrated, in the electronic device ED, the image IM may be displayed only on a selected surface among the side surfaces SS1, SS2, SS3, and SS4 of the window 100 or the image IM may be displayed only on the front surface and the image IM may not displayed on the side surfaces SS1, SS2, SS3, and SS4, but the present disclosure is not limited to an embodiment.

In an embodiment, the electronic device ED may sense the external input TC applied to the plurality of side surfaces SS1, SS2, SS3, and SS4 as well as the front surface of the window 100. However, this is illustratively illustrated, and the electronic device ED may sense the external input TC applied to a selected surface among the side surfaces SS1, SS2, SS3, and SS4 of the window 100 or may not sense the external input TC input to the side surfaces SS1, SS2, SS3, and SS4, but the present disclosure is not limited to an embodiment.

In an embodiment, the window 100 may have a three-dimensional shape. That is, at least a portion of the window 100 may include a curved surface. The window 100 may include a flat portion 110 and a curved portion 120. The flat portion 110 correspond to a front surface having a planar shape perpendicular to the third direction DR3. The curved portion 120 provides a front surface having a shape that is inclined with respect to the third direction DR or curved with respect an axis in the second direction DR2. The flat portion 110 of the front surface may correspond to the front surface described above, and the curved portion 120 of the front surface may correspond to the side surfaces SS1, SS2, SS3, and SS4 described above.

The flat portion 110 includes a front surface and a rear surface opposite to each other. The front surface and the rear surface of the flat portion 110 may be flat surfaces. That is, each of the front surface and the rear surface of the flat portion 110 may be parallel to a plane defined by the first direction DR1 and the second direction DR2. Each of the front surface and the rear surface of the flat portion 110 may be perpendicular to a linear line parallel to the third direction DR3. That is, a direction in which a thickness of the flat portion 110 is defined may be the third direction DR3, i.e., the thickness direction of the flat portion 110 is the third direction DR3.

The flat portion 110 may include or be defined by a first member (or a first material). The first member may include glass. The first member may have a crystalline structure. The first member may include glass crystallized through a crystallization process. The first member may have a high crystallinity degree of about 60% or greater. The first member may be formed through low-temperature thermoforming.

The curved portion 120 includes a front surface and a rear surface opposite to each other. The front surface and/or the rear surface of the curved portion 120 may include at least one curved surface. The front surface of the curved portion 120 may be curved with respect to the front surface of the flat portion 110. A direction in which a thickness of the curved portion 120 is defined may be a direction that is different from the third direction DR3 and intersects the third direction DR3.

The curved portion 120 may include glass but may have a different crystal structure from that of the flat portion 110. Accordingly, the curved portion 120 may have different haze and processability from those of the flat portion 110. In an embodiment, for example, the curved portion 120 may include a second member (or a second material) having a different crystal structure from that of the first member. The second member may have an amorphous structure. The second member may have a lower crystallinity degree than that of the first member. The second member may be formed through thermoforming in a relatively high temperature environment as compared to the first member.

The first member may have better haze characteristics than the second member. That is, the first member may have relatively high and clear light transmittance (light transparency) as compared to the second member.

in an embodiment, the second member may have a lower viscosity than that of the first member. Further, the second member may have lower breakage characteristics than that of the first member. Accordingly, the second member may have improved processability as compared to the first member.

The flat portion 110 and the curved portion 120 may be directly coupled to each other. The flat portion 110 and the curved portion 120 are physically coupled to each other. Accordingly, a predetermined boundary area may be formed between the flat portion 110 and the curved portion 120. The boundary area may be formed by melting the first member of the flat portion 110 and the second member of the curved portion 120. A detailed description thereof will be made below.

According to an embodiment of the present disclosure, the flat portion 110, on which the image is displayed, is formed using the first member having high light transmittance, the curved portion 120 including the curved surface is formed using the second member having high processability, and thus the window including the curved surface may be provided. The window may have improved haze characteristics or improved processability as compared to a window made of a single material. Accordingly, the curved window having high transparency and improved reliability may be provided.

In an embodiment, the housing 200 is coupled to the window 100 to define an outer surface of the electronic device ED. The housing 200 provides an internal space in which the display panel 300 may be accommodated. The housing 200 provides an accommodation space in which the display panel 300 and other components (not illustrated) constituting the electronic device ED may be accommodated and protects internal components from an external impact.

The display panel 300 may provide a display surface DS. The display panel 300 includes a plurality of pixels PX that display the image IM on the display surface DS. Each of the pixels PX may include a display element and a pixel driving circuit for driving the pixels PX. The display element may include various elements such as organic light emitting elements, liquid crystal capacitors, quantum dot light emitting elements, light emitting diodes (LEDs), or ultra-small LEDs, but the present disclosure is not limited to an embodiment.

The display panel 300 may include a main part P0 and a plurality of cut parts P1, P2, P3, and P4. The main part P0 may be disposed parallel to the front surface FS and may have a shape corresponding to the front surface FS. The main part P0 may include a main display area AA0 for providing the image IM to the front surface FS.

The cut parts P1, P2, P3, and P4 may include first to fourth cut parts P1, P2, P3, and P4. The first to fourth cut parts P1, P2, P3, and P4 are arranged on sides of the main part P0 and protrude from the main part P0. The first to fourth cut parts P1, P2, P3, and P4 may include sub-display areas AA1, AA2, AA3, and AA4 (hereinafter, referred to as first to fourth display area) for providing images IM 1, IM 2, IM 3, and IM 4 to the first to fourth side surfaces SS1, SS2, SS3, and SS4, respectively.

In an embodiment, as shown in FIG. 2, the pixels PX may be arranged in the display areas AA0, AA1, AA2, AA3, and AA4, respectively, and emit lights. The pixels PX may be classified into a plurality of pixel groups PX G0, PX G1, PX G2, PX G3, and PX G4. Among the pixel groups PX G0, PX G1, PX G2, PX G3, and PX G4, the main pixel group PX G0 may be disposed on the main display area AA0. An image displayed by the main pixel group PX G0 may be visually recognized from the outside through the front surface FS.

Among the pixel groups PX G0, PX G1, PX G2, PX G3, and PX G4, the first sub-pixel group PX G1 may be disposed on the first display area AA1. An image displayed by the first sub-pixel group PX G1 may be visually recognized from the outside through the first side surface SS1. Among the pixel groups PX G0, PX G1, PX G2, PX G3, and PX G4, the second sub-pixel group PX G2 may be disposed on the second display area AA2. An image displayed by the second sub-pixel group PX G2 may be visually recognized from the outside through the second side surface SS2. Among the pixel groups PX G0, PX G1, PX G2, PX G3, and PX G4, the third sub-pixel group PX G3 may be disposed on the third display area AA3. An image displayed by the third sub-pixel group PX G3 may be visually recognized from the outside through the third side surface SS3. Among the pixel groups PX G0, PX G1, PX G2, PX G3, and PX G4, the fourth sub-pixel group PX G4 may be disposed on the fourth display area AA4. An image displayed by the fourth sub-pixel group PXG4 may be visually recognized from the outside through the fourth side surface SS4.

The pixel groups PX G0, PX G1, PXG2, PX G3, and PX G4 may display images independent from each other or display images related to each other. In an embodiment, for example, images displayed on the display areas AA0, AA1, AA2, AA3, and AA4 may display one image. Alternatively, an image including main information may be displayed on the main display area AA0, and icons requiring input of the user or button images for controlling the image displayed on the main display area AA0 may be displayed on the first to fourth display areas AA1, AA2, AA3, and AA4. The pixel groups PX G0, PX G1, PX G2, PX G3, and PX G4 may be connected to and driven by one driving circuit or may be driven independently through separate driving circuits that are independent of each other, but the present disclosure is not limited to an embodiment.

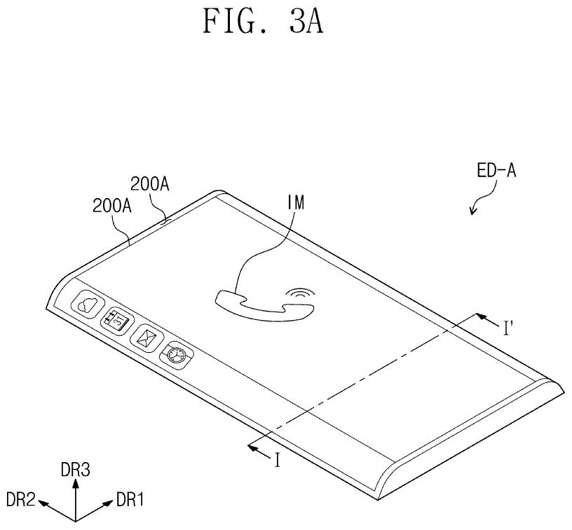

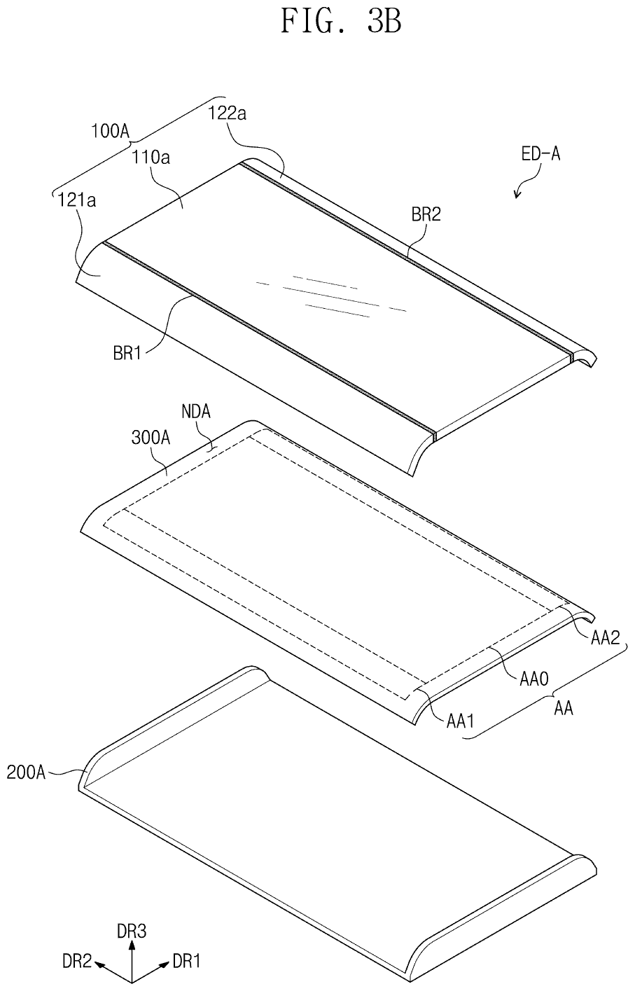

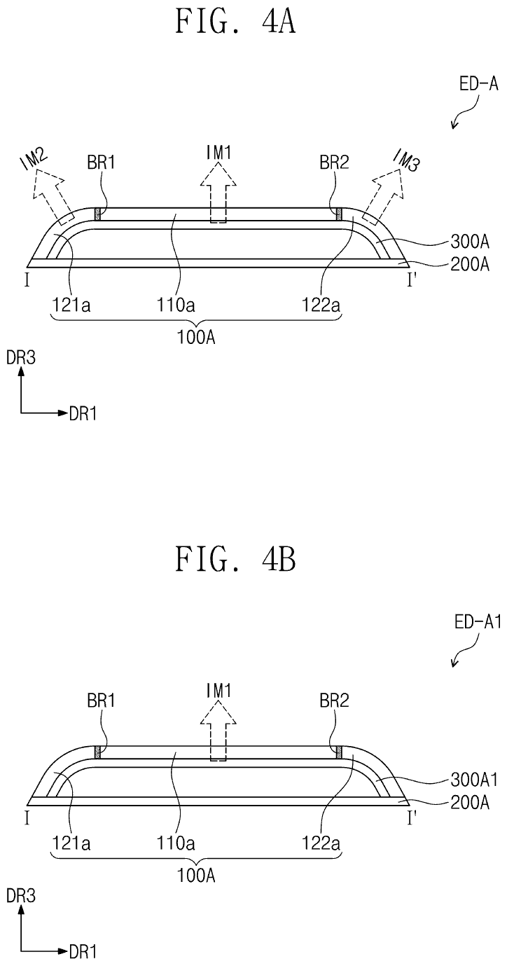

FIG. 3A is a perspective view of the electronic device according to an embodiment of the present disclosure. FIG. 3B is an exploded perspective view of the electronic device illustrated in FIG. 1A. FIGS. 4A and 4B are cross-sectional views of the electronic device illustrated in FIG. 3A. For easy description, some components will be omitted in FIGS. 3A to 4B. Hereinafter, an electronic device according to an embodiment of the present disclosure will be described with reference to FIGS. 3A to 4B. In FIGS. 3A to 4B, the same reference numerals are given to the same components as those described above with reference to FIGS. 1A to 2B, and any repetitive detailed descriptions thereof will be omitted or simplified.

As illustrated in FIGS. 3A to 4B, in an embodiment of an electronic device ED-A, a window 100A may include a flat portion 110a and a plurality of curved portions 121a and 122a (hereinafter, referred to as first and second curved portions). The flat portion 110a and the curved portions 121a and 122a may be physically joined to each other and provided to the window 100A having an integrated shape.

The flat portion 110a includes a front surface on a plane perpendicular to the third direction DR3. The first and second curved portions 121a and 122a are spaced apart from each other in the first direction DR1 with the flat portion 110a interposed therebetween. Each of the first and second curved portions 121a and 122a is curved with respect to the flat portion 110a. A front surface of each of the first and second curved portions 121a and 122a includes a curved surface curved with respect to an axis in the second direction DR2. The first and second curved portions 121a and 122a may be coupled to one side and the other side of the flat portion 110a, respectively. Accordingly, the window 100A may include a first joining area BR1 formed between the first curved portion 121a and the flat portion 110a and a second joining area BR2 formed between the second curved portion 122a and the flat portion 110a.

A housing 200A is coupled to the window 100A to define an outer surface of the electronic device ED-A. The housing 200A provides an internal space in which a display panel 300A may be accommodated. The housing 200A provides an accommodation space in which the display panel 300A and other components (not illustrated) constituting the electronic device ED may be accommodated and protects internal components from an external impact. The housing 200A may be provided in various shapes depending on a shape of the window 100A.

The display panel 300A includes a display area AA and a peripheral area NDA. The display area AA may include a main display area AA0, a first display area AA1, and a second display area AA2. The image IM may be displayed on each of the display areas AA0, AA1, and AA2.

In detail, referring to FIG. 4A, the display panel 300A may display the image IM (shown in FIG. 3A) on each of the front surface FS and the side surfaces SS1 and SS2 of the window 100A. In an embodiment, a first image IM 1 displayed in the main display area AA0 of the display panel 300A may be visually recognized through the flat portion 110a, a second image IM 2 displayed in the first display area AA1 may be visually recognized through the first curved portion 121a of the window 100A, and a third image IM 3 displayed in the second display area AA2 may be visually recognized through the second curved portion 122a of the window 100A.

That is, the flat portion 110a may transmit the first image IM 1, the first curved portion 121a may transmit the second image IM 2, and the second curved portion 122a may transmit the third image IM 3. The first curved portion 121a and the second curved portion 122a may have relatively high haze and low light transmittance as compared to the flat portion 110a. However, when transmittance of each of the first curved portion 121a and the second curved portion 122a is sufficient for the image to be visually recognized, the image output from the display panel 300A may be visually recognized through the side surfaces SS1 and SS2 as well as the front surface FS, and thus the electronic device ED-A may be provided as a multi-surface display.

In another embodiment, as illustrated in FIG. 4B, a display panel 300A1 may provide an image only to the main display area AA0. In such an embodiment, the curved portions 121a and 122a of the window 100A may have processability without consideration of haze characteristics thereof, and thus the window 100A may be provided in various shapes in which flexibility of the curved portions 121a and 122a increases or the like.

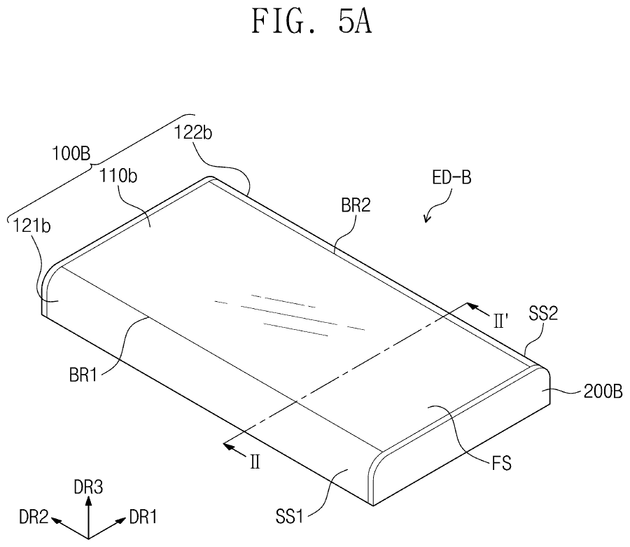

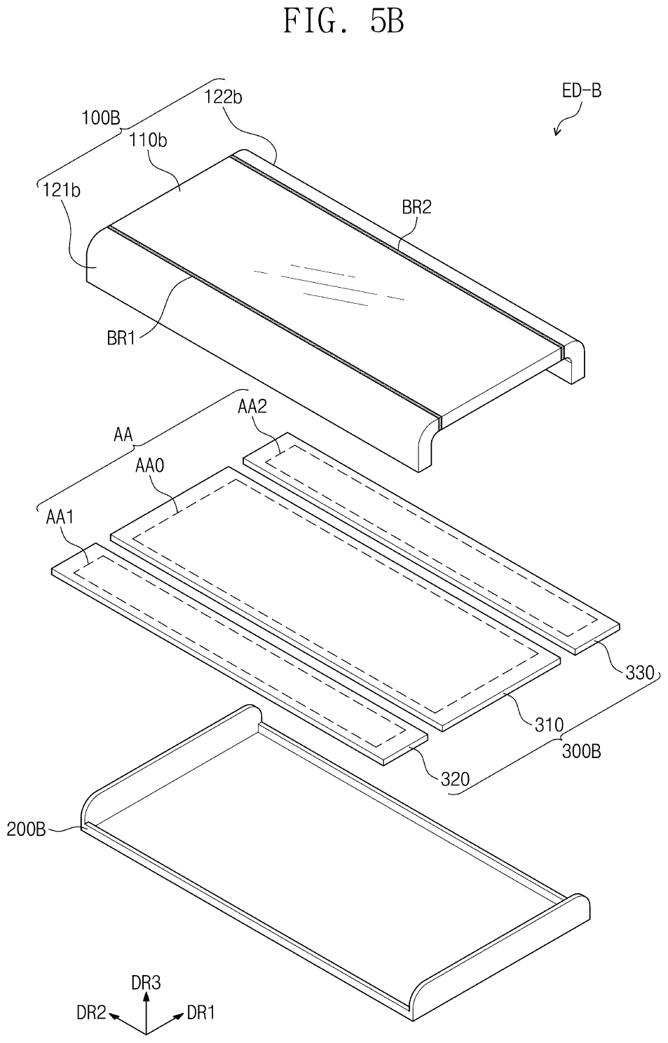

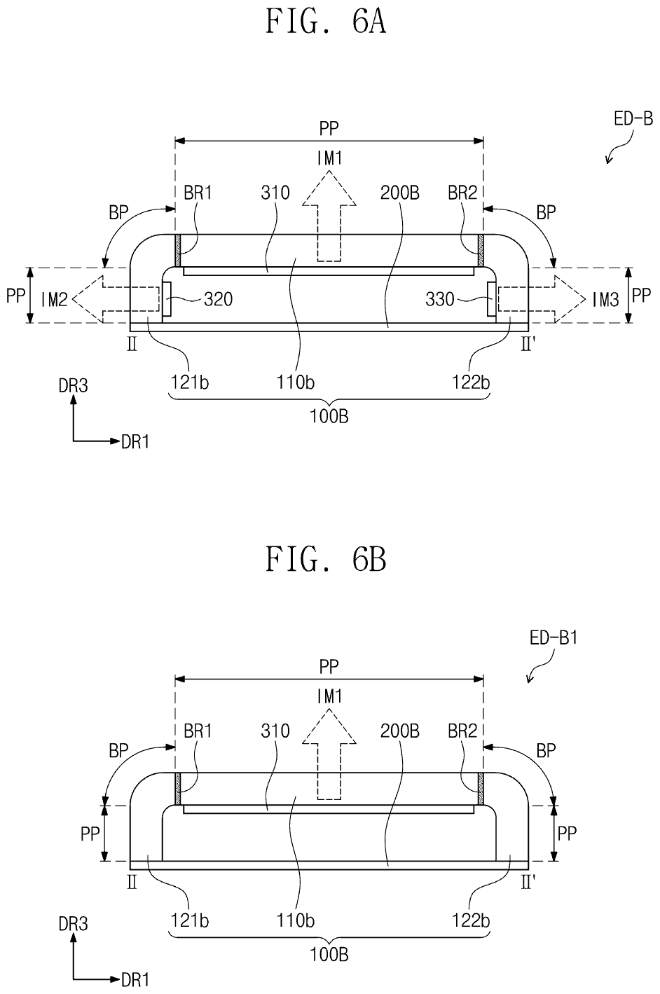

FIG. 5A is a perspective view of the electronic device according to an embodiment of the present disclosure. FIG. 5B is an exploded perspective view of the electronic device illustrated in FIG. 5A. FIGS. 6A and 6B are cross-sectional views of the electronic device illustrated in FIG. 5A. For easy description, some components will be omitted in FIGS. 5A to 6B. Hereinafter, an electronic device according to an embodiment of the present disclosure will be described with reference to FIGS. 5A to 6B. In FIGS. 5A to 6B, the same reference numerals are given to the same components as those described above with reference to FIGS. 1A to 4B, and any repetitive detailed descriptions thereof will be omitted.

As illustrated in FIGS. 5A to 6B, in an embodiment of an electronic device ED-B, a window 100B may include a flat portion 110b and a plurality of curved portions 121b and 122b (hereinafter, referred to as first and second curved portions). The flat portion 110b includes a front surface on a plane perpendicular to the third direction DR3. The flat portion 110b may correspond to the flat portion 110a (see FIG. 3B) illustrated in FIG. 3B.

The first and second curved portions 121b and 122b are spaced apart from each other in the first direction DR1 with the flat portion 110b interposed therebetween. Each of the first and second curved portions 121b and 122b is curved with respect to the flat portion 110b, and a front surface of each of the first and second curved portions 121b and 122b includes a curved surface curved with respect to an axis in the second direction DR2. Each of the first and second curved portions 121b and 122b may have a more curved shape than those of the first and second curved portions 121a and 122a illustrated in FIG. 3B.

In an embodiment, referring to FIGS. 6A and 6B, an entire portion of a front surface of the flat portion 110b may be a flat surface PP. The flat surface PP of the flat portion 110b may be a surface perpendicular to the third direction DR3. Each of the first and second curved portions 121b and 122b may include the flat surface PP and a curved surface BP. The flat surface PP may be a surface perpendicular to the first direction DR1. The curved surface BP may be a surface curved with respect to an axis in the second direction DR2. The curved surface BP connects the front surface of the flat portion 110b and the front surfaces of the curved portions 121b and 122b.

According to an embodiment of the present disclosure, the first and second curved portions 121b and 122b including the curved surface BP and the flat portion 110b are independently provided and physically joined to each other, and thus the window 100B having joining areas BR1 and BR2 may be provided. The first and second curved portions 121b and 122b including the curved surface BP and the flat portion 110b not having a curved surface include or are formed of different materials, respectively, and thus processability for forming the curved surface BP may be secured differently and independently in the flat portion 110b and the curved portions 121b and 122b.

The first and second curved portions 121b and 122b may be coupled to one side and an opposing side of the flat portion 110a, respectively. Accordingly, the window 100A may include the first joining area BR1 formed between the first curved portion 121b and the flat portion 110a and the second joining area BR2 formed between the second curved portion 122b and the flat portion 110a.

Referring to FIG. 6A, an embodiment of the electronic device ED-B may display images on the front surface FS and the side surfaces SS1 and SS2 of the window 100B. The first image IM 1 displayed on a first display unit 310 may be visually recognized through the flat portion 110b, the second image IM 2 displayed on a second display unit 320 may be visually recognized through the first curved portion 121b of the window 100B, and the third image IM 3 displayed on a third display unit 330 may be visually recognized through the second curved portion 122b of the window 100B.

Alternatively, referring to FIG. 6B, an electronic device ED-B1 may include only the first display unit 310. In such an embodiment, the window 100B may transmit the first image IM 1 through the flat portion 110b, and the image may not be visually recognized through the curved portions 121b and 122b. Accordingly, in the window 100B, only the flat portion 110b includes or is formed of a material having high light transmittance, the curved portions 121b and 122b include or are formed of a material having high processability without considering transmittance thereof, and thus the degree of freedom in selecting a material of the window 100B may be improved.

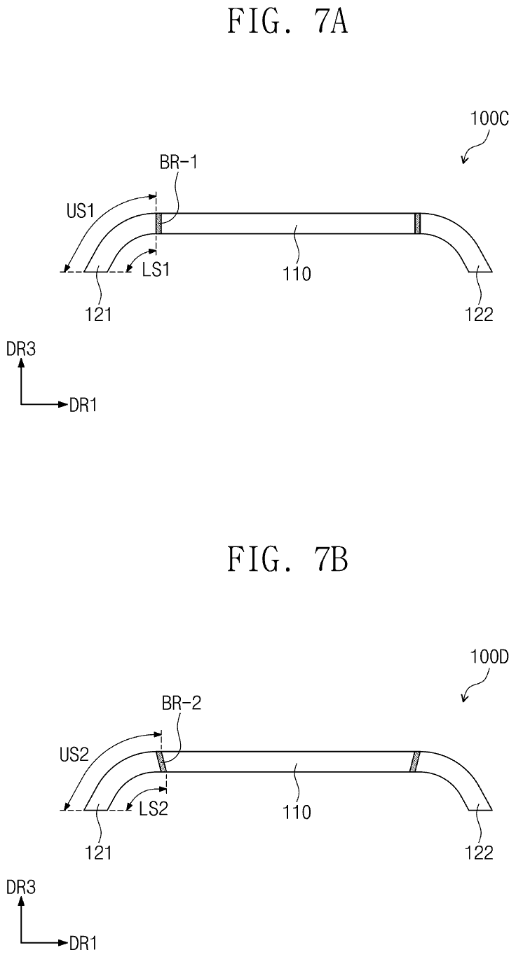

FIGS. 7A and 7B are cross-sectional views of a window according to an embodiment of the present disclosure. A window according to an embodiment of the present disclosure will be described with reference to FIGS. 7A to 7B. In FIGS. 7A and 7B, the same reference numerals are given to the same components as those described above with reference to FIGS. 1A to 6B, and any repetitive detailed descriptions thereof will be omitted.

As illustrated in FIG. 7A, in an embodiment of a window 100C, a cross-sectional shape of a joining area BR-1 may be parallel to the third direction DR3. In such an embodiment, the flat portion 110 may have a quadrangular plate shape having a plane parallel to the first direction DR1 and the second direction DR2 and a side surface parallel to the third direction DR3.

A cross-section of the flat portion 110 may have a rectangular shape. In such an embodiment, because the joining area BR-1 is formed along a side surface of the flat portion 110, a cross-section of the joining area BR-1 may have a shape substantially parallel to the third direction DR3.

Alternatively, as illustrated in FIG. 7B, in a window 100D, a cross-sectional shape of a joining area BR-2 may be inclined in the third direction DR3. In such an embodiment, the flat portion 110 may have a trapezoidal plate shape having a flat surface parallel to the first direction DR1 and the second direction DR2 and a side surface inclined in the third direction DR3.

In an embodiment, a cross-section of the flat portion 110 may have a trapezoidal shape. In such an embodiment, because the joining area BR-2 is formed along the side surface of the flat portion 110, a cross-section of the joining area BR-2 may have a diagonal shape inclined with respect to the third direction DR3. Front surfaces US2 of the curved portions 121 and 122 illustrated in FIG. 7B may be the same as front surfaces US1 of the curved portions 121 and 122 illustrated in FIG. 7A, but rear surfaces LS2 of the curved portions 121 and 122 illustrated in FIG. 7B may have larger areas than rear surfaces LS1 of the curved portions 121 and 122 illustrated in FIG. 7A.

According to an embodiment of the present disclosure, the shapes of the joining areas BR-1 and BR-2 may be variously changed or modified depending on the shape of the flat portion 110, and the present disclosure is not limited to an embodiment.

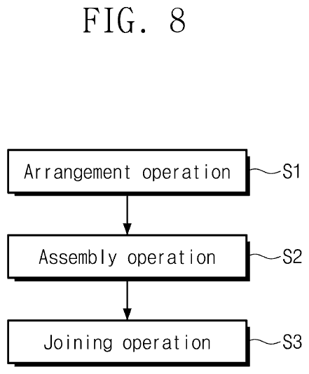

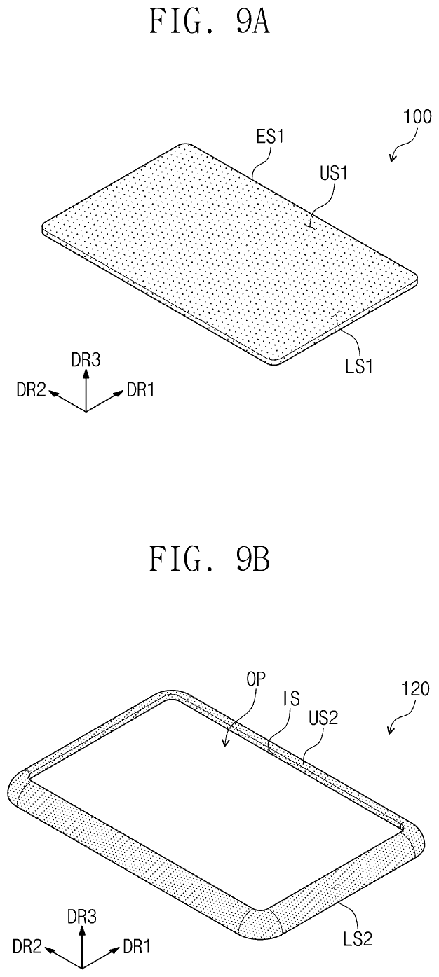

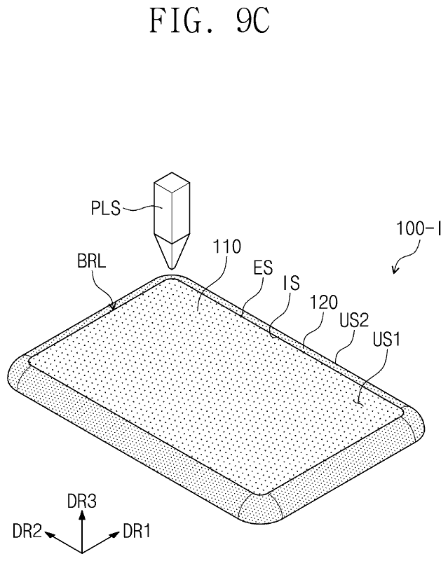

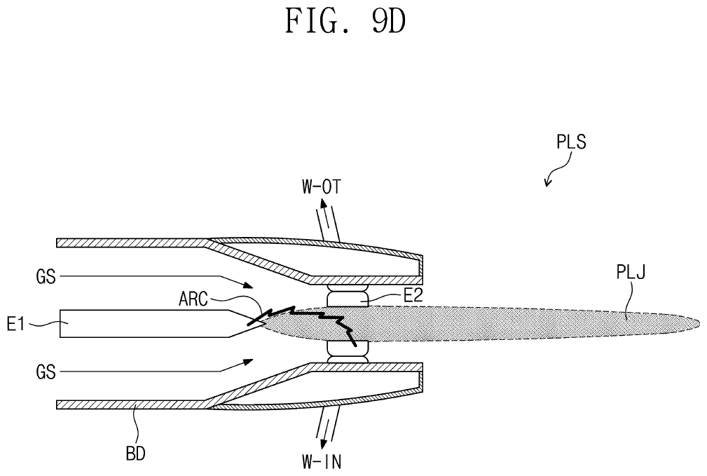

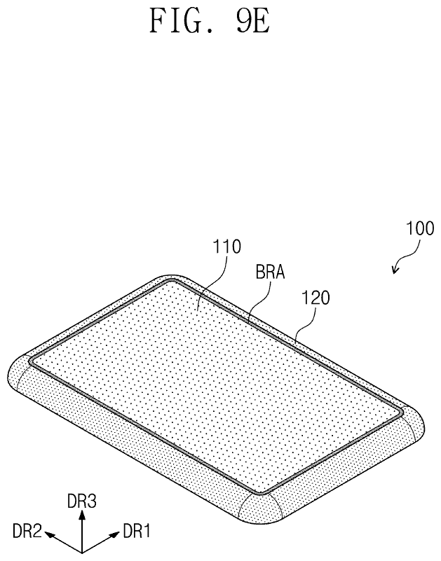

FIG. 8 is a schematic flowchart illustrating a method of manufacturing a window according to an embodiment of the present disclosure. FIGS. 9A to 9E are views illustrating the method of manufacturing the window according to an embodiment of the present disclosure. Hereinafter, a method of manufacturing a window according to an embodiment of the present disclosure will be described with reference to FIGS. 8 to 9E. In FIGS. 8 to 9E, the same reference numerals are given to the same components as those described in FIGS. 1A to 7B, and any repetitive detailed descriptions thereof will be omitted.

As illustrated in FIG. 8, an embodiment of a method of manufacturing a window may include performing an arrangement operation S1, performing an assembly operation S2, and performing a joining operation S3.

FIGS. 9A and 9B may correspond to the arrangement operation S1 of FIG. 8. The flat portion 110 and the curved portion 120 may be provided separately. That is, the flat portion 110 and the curved portion 120 may be formed and provided independently of each other. In FIGS. 9A to 9E, for easy illustration, each of the flat portion 110 and the curved portion 120 is shaded.

Referring to FIG. 9A, the flat portion 110 may have a flat surface plate shape on the plane defined by the first direction DR1 and the second direction DR2. That is, the flat portion 110 may include a front surface US1, a rear surface LS1 opposite to the front surface US1 in the third direction DR3, and an outer surface ES connected between the front surface US1 and the rear surface LS1.

Each of the front surface US1 and the rear surface LS1 of the flat portion 110 may be parallel to the plane defined by the first direction DR1 and the second direction DR2. The front surface US1 and the rear surface LS1 of the flat portion 110 may not include a curved surface on a cross section of the flat portion 110.

The outer surface (or outer sides surfaces) ES of the flat portion 110 connects the front surface US1 and the rear surface LS1. In an embodiment, the outer surface ES of the flat portion 110 may have a curved surface defining a curved line (e.g., a rounded corner portion) on the plane defined by the first direction DR1 and the second direction DR2. However, this is illustratively illustrated, the outer surface ES may have only a flat surface defining a linear line on the plane defined by the first direction DR1 and the second direction DR2, but the present disclosure is not limited thereto.

In an embodiment, as described above, the flat portion 110 may include the first member. The first member may be formed by crystallizing glass. The first member may be crystallized glass or ceramic glass. The first member may be glass having a crystallinity degree of at least 60% or greater. The first member is formed by heat-treating the glass twice. A nano-sized crystal phase may be formed inside the first member. Accordingly, the flat portion 110 may have improved durability as compared to glass that is not heat-treated. Further, the flat portion 110 may have higher light transmittance than that of the curved portion 120.

Referring to FIG. 9B, the curved portion 120 may have an annular shape defining a predetermined opening OP. In an embodiment, the curved portion 120 may include a front surface US2 having at least a curved portion thereof, a rear surface LS2 opposite to the front surface US2, and an inner surface IS connected between the front surface US2 and the rear surface LS2 and defining the opening OP. In an embodiment, the rear surface LS2 may have a curved surface that is convex toward the third direction DR3. That is, the curved portion 120 may be curved and formed through a bending process or a folding process. However, this is illustratively illustrated, the rear surface LS2 may have a flat surface, and the curved portion 120 may be formed to include a curved surface on the front surface US2 through a chamfering process, but the present disclosure is not limited to an embodiment.

The inner surface IS may be a surface that faces a side surface ES1 of the flat portion 110 in the assembly operation S2, which will be described below. The opening OP of the curved portion 120 may have the same shape as the flat portion 110, and the curved portion 120 may have a frame shape surrounding an edge of the flat portion 110 in a plan view or when viewed in the third direction DR3. However, this is illustratively illustrated, and the curved portion 120 may have various shapes as long as the shapes include one surface facing at least one side surface of the flat portion 110, but the present disclosure is not limited to an embodiment.

As described above, the curved portion 120 may include the second member. The second member may be amorphous glass or glass having a relatively low crystallinity degree as compared to the first member. Accordingly, the curved portion 120 may have improved processability and high ductility as compared to the flat portion 110. Accordingly, the curved portion 120 may be relatively stably curved as compared to the flat portion 110.

FIGS. 9C to 9E may correspond to the assembly operation S2 and the joining operation S3 of FIG. 8. Referring to FIG. 9C, in the assembly operation S2, the flat portion 110 and the curved portion 120 may be arranged such that at least a portion of the side surface ES1 of the flat portion 110 and at least a portion of the inner surface IS of the curved portion 120 face each other. In an embodiment, the side surface ES1 of the flat portion 110 may be disposed to entirely face the inner surface IS of the curved portion 120. In other words, in the assembly operation S2, the flat portion 110 may be inserted and assembled into the opening OP of the curved portion 120. However, this is illustratively illustrated, and the curved portion 120 may be assembled to partially face the side surface ES1 of the flat portion 110 according to the shape of the curved portion 120, but the present disclosure is not limited to an embodiment.

Referring to FIGS. 9C and 9E, an initial window 100-I in which the flat portion 110 and the curved portion 120 are assembled may be formed into the window 100 through the joining operation S3 using a bonding machine PLS. The bonding machine PLS may join the flat portion 110 and the curved portion 120 while moving along a joining line BRL. The joining line BRL may be a boundary line formed through contact between the outer surface ES of the flat portion 110 and the inner surface IS of the curved portion 120.

Referring to FIG. 9D, an embodiment of the bonding machine PLS includes a first electrode E1 and a second electrode E2 arranged inside a cylindrical body part BD. The first electrode E1 and the second electrode E2 may be electrodes having opposite polarities, the first electrode E1 may be a cathode, and the second electrode E2 may be an anode. The first electrode E1 may have a sharp tip portion. In such an embodiment, a predetermined gas GS is provided into the body part BD, and a high potential difference is applied between the first electrode E1 and the second electrode E2, such that arc discharge ARC is generated between the tip portion of the first electrode E1 and the second electrode E2. The gas GS may be ionized by the arc discharge ARC to form a plasma jet PLJ. In an embodiment, the bonding machine PLS may include a coolant inlet W-IN and a coolant outlet W-OUT. However, this is illustratively illustrated, in the bonding machine PLS, the coolant inlet W-IN and the coolant outlet W-OUT may be omitted, and the present disclosure is not limited to an embodiment. In an embodiment, the bonding machine PLS may further provide a shielding gas to a vicinity of the plasma jet PLJ to improve a concentration of the plasma jet PLJ.

The plasma jet PLJ is applied along the joining line BRL to join the flat portion 110 and the curved portion 120. The flat portion 110 and the curved portion 120 may be welded to each other to form a welded area BRA of FIG. 9E. Therefore, the flat portion 110 and the curved portion 120 may be physically coupled to each other.

According to an embodiment of the present disclosure, the window 100 is formed through bonding using the bonding machine PLS, and thus the flat portion 110 and the curved portion 120 having different members may be stably joined to each other, a process may be simplified, and a process time may be shortened. In such an embodiment, in the window 100, the flat portion 110 and the curved portion 120 are independently provided, and thus a processing process of the curved portion 120 may be simplified. In such an embodiment, the degree of curvature of the curved portion 120 may be diversified, and thus the window 100 having various shapes may be easily provided.

According to an embodiment of the present disclosure, a three-dimensional (3D) window having improved light transmittance and improved processability may be provided.

Further, according to an embodiment of the present disclosure, a window may be easily manufactured by joining different members.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A window comprising:
a flat portion including a crystalline glass; and
a curved portion including glass having a crystallinity degree lower than a crystallinity degree of the flat portion and coupled to the flat portion,
wherein the curved portion is curved with respect to the flat portion, and
wherein a front surface of the curved portion includes a curved surface, and a front surface of the flat portion includes only a flat surface.

2. The window of claim 1, wherein a joining area is defined between the flat portion and the curved portion, and
wherein the joining area is formed of only glass.

3. The window of claim 2, wherein the joining area has a frame shape surrounding an edge of the flat portion in a plan view.

4. The window of claim 2, wherein the curved portion is provided in plural, and a plurality of curved portions is spaced part from each other with the flat portion interposed therebetween, and
wherein the joining area is provided in plural, and a plurality of joining areas is provided on one side and an opposing side of the flat portion.

5. The window of claim 1, wherein the flat portion includes glass having a crystallinity degree of about 60% or greater.

6. The window of claim 1, wherein the curved portion includes amorphous glass.

7. The window of claim 1, wherein a rear surface of the curved portion includes a flat surface.

8. The window of claim 1, wherein a rear surface of the curved portion includes a curved surface.

9. The window of claim 1, wherein a rear surface of the flat portion has a same area as the front surface of the flat portion.

10. The window of claim 1, wherein a rear surface of the flat portion has a smaller area than the front surface of the flat portion.

11. An electronic device comprising:
a display panel including a flat surface;
a window disposed on the display panel; and
a housing disposed under the display panel and coupled with the window,
wherein the window includes:
a flat portion corresponding to the flat surface and including a first member; and
a curved portion including a second member having a crystallinity degree lower than a crystallinity degree of the first member, and coupled to the flat portion, and
wherein the curved portion includes a surface inclined with respect to a front surface of the flat portion.

12. The electronic device of claim 11, wherein the flat portion has a light transmittance higher than a light transmittance of the curved portion.

13. The electronic device of claim 11, wherein the curved portion has ductility higher than ductility of the flat portion.

14. The electronic device of claim 11, wherein the flat portion has impact resistance higher than impact resistance of the curved portion.

15. The electronic device of claim 11, wherein the display panel displays an image only on the flat portion.

16. The electronic device of claim 11, wherein the display panel displays an image on the flat portion and the curved portion.

17. A method of manufacturing a window, the method comprising:
providing a flat portion formed of a first member and including a first front surface which is flat, a first rear surface which is opposite to the first front surface and flat, and an outer surface connected between the first front surface and the first rear surface;
providing a curved portion formed of a second member different from the first member and including a second front surface including a surface inclined with respect to the first front surface, a second rear surface opposite to the second front surface, and a side surface connected between the second front surface and the second rear surface;
assembling the flat portion and the curved portion to form a joining line in which the outer surface of the flat portion faces at least a portion of the side surface of the curved portion; and
joining the flat portion and the curved portion to form a joining area along the joining line through a plasma fusion bonding process.

18. The method of claim 17, wherein the first member includes crystalline glass, and
wherein the second member includes glass having a crystallinity degree lower than a crystallinity degree of the first member.

19. The method of claim 18, wherein the crystallinity degree of the first member is about 60% or greater.

20. The method of claim 17, wherein the second member includes amorphous glass.

21. The method of claim 17, wherein
the flat portion and the curved portion are physically separated from each other along the joining line in the assembling of the flat portion, and
the curved portion and are physically coupled to each other along the joining area in the joining of the flat portion and the curved portion.

22. The method of claim 17, wherein the curved portion is formed through a chamfering process.

23. The method of claim 17, wherein the curved portion is formed through a bending process.
